(19) United States
(12) Patent Application Publication
(10) Pub. No.: US 2024/0395945 A1
(43) Pub. Date: Nov. 28, 2024

(54) SEMICONDUCTOR DEVICE

(71) Applicant: ROHM CO., LTD., Kyoto (JP)

(72) Inventor: Chikara TERADA, Kyoto-shi (JP)

(73) Assignee: ROHM CO., LTD., Kyoto (JP)

(21) Appl. No.: 18/670,617

(22) Filed: May 21, 2024

(30) Foreign Application Priority Data
May 25, 2023 (JP) 2023-085987

(51) Int. Cl. H01L 29/808; H01L 29/06; H01L 29/40

(52) U.S. Cl. CPC H01L 29/808; H01L 29/0692; H01L 29/402

(57) ABSTRACT

A semiconductor device includes a semiconductor substrate, a semiconductor layer located on the semiconductor substrate, a drain region; a source/gate region, an insulating layer located above the semiconductor layer, and a field plate located on the insulating layer, wherein the field plate includes an innermost periphery, an outermost periphery, a first straight line portion and a second straight line portion located between the innermost periphery and the outermost periphery, and a first connection portion connecting the first straight line portion and the second straight line portion, wherein each of the innermost periphery, the outermost periphery, the first straight line portion, the second straight line portion and the first connection portion is a part of a current path, and wherein each of the first straight line portion and the second straight line portion extends in a second direction intersecting with the first direction in a plan view.

### CROSS REFERENCE TO RELATED APPLICATIONS

This application claims the benefit of priority to Japanese Patent Application No. 2023-085987 filed on May 25, 2023. The entire contents of the above-identified application are hereby incorporated by reference.

### TECHNICAL FIELD

The present disclosure relates to a semiconductor device.

### BACKGROUND

Japanese Patent Publication No. 2017-208420 discloses a semiconductor device including a junction field effect transistor (JFET). This semiconductor device includes a p-type semiconductor substrate, an n-type semiconductor layer formed on the semiconductor substrate, an n-type drain region formed at a surface region of an n-type semiconductor region, a plurality of n-type source regions formed at the surface region of the semiconductor region spaced apart from the drain region, a p-type gate region formed at the semiconductor region between the source regions, and a resistive field plate having a spiral shape in a plan view disposed on the semiconductor region between the drain region and the source region and electrically connected to the drain region and ground.

### BRIEF DESCRIPTION OF DRAWINGS

FIG. 1 is a plan view showing a chip of a semiconductor device according to an embodiment.

FIG. 2 is a schematic cross-sectional view taken along line II-II shown in FIG. 1.

FIG. 3 is an enlarged view of a portion surrounded by an alternate long and short dash line III shown in FIG. 2.

FIG. 4 is a cross-sectional view taken along line IV-IV shown in FIG. 2.

FIG. 5 is an enlarged view of a main part of FIG. 4.

FIG. 6A is an enlarged view of a portion surrounded by a broken line VIa in FIG. 4, and FIG. 6B is an enlarged view of a portion surrounded by a broken line VIb in FIG. 4.

FIG. 7 is an enlarged view of a main part of FIG. 4.

FIG. 8 is a schematic cross-sectional view taken along line VIII-VIII shown in FIG. 7.

FIG. 9 is a schematic cross-sectional view taken along line IX-IX shown in FIG. 7.

FIG. 10 is a schematic plan view showing a field plate included in an FET structure according to a comparative example.

FIG. 11 is a schematic plan view showing a field plate according to a modification.

FIG. 12 is a schematic cross-sectional view for explaining the electrical connection between the straight line portion and the curved line portion of the outermost periphery.

### DETAILED DESCRIPTION

Hereinafter, embodiments of the present disclosure will be described in detail with reference to the accompanying drawings. In the following description, the same reference numerals are used for identical elements or elements having identical functions, and redundant description will be omitted. “Identical” and words similar thereto in this specification are not limited to only “completely identical”. In addition, since the drawings are for conceptually describing the embodiments, the dimensions of each components represented and the ratios thereof may be different from actual ones.

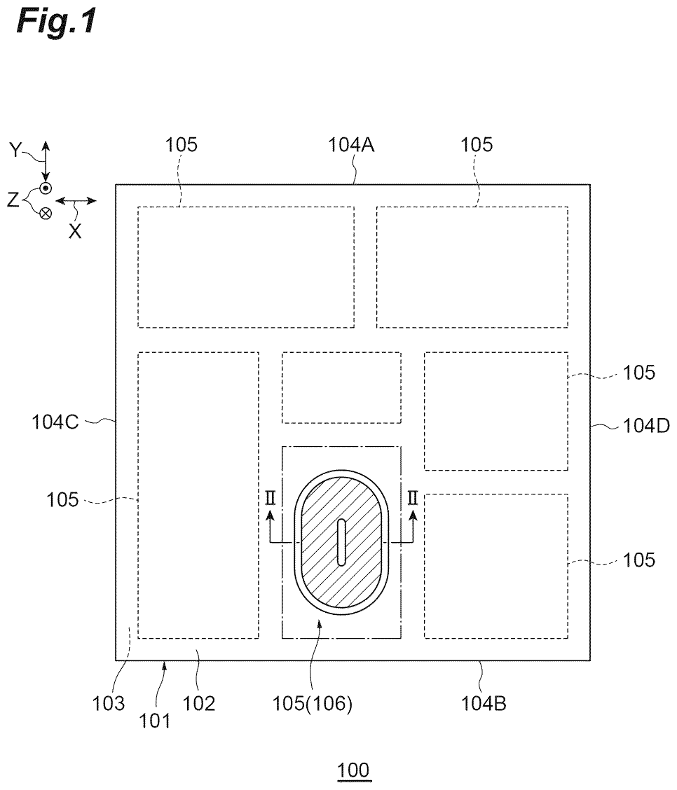

FIG. 1 is a plan view showing a chip of a semiconductor device according to an embodiment. As shown in FIG. 1, the semiconductor device 100 includes a chip 101 (semiconductor chip) made of silicon having a rectangular parallelepiped shape. The chip 101 has a first main face 102 and a second main face 103 that are a pair of main surfaces, and a first side face 104A, a second side face 104B, a third side face 104C and a fourth side face 104D that connect the first main face 102 and the second main face 103. In the following description, an extending direction of the first side face 104A and the second side face 104B in a plan view is referred to as a first direction X, an extending direction of the third side face 104C and the fourth side face 104D in a plan view is referred to as a second direction Y, and a normal direction of the first main face 102 and the second main face 103 is referred to as a third direction Z. The second direction Y is a direction intersecting the first direction X in a plan view, and the third direction Z corresponds to a thickness direction of the chip 101.

The first main face 102 and the second main face 103 are formed in a quadrangular shape when viewed from the third direction Z, but are not limited thereto. In the present embodiment, the first main face 102 is the top surface, and the second main face 103 is the bottom surface. Therefore, a configuration located near the first main face 102 in the third direction Z corresponds to a configuration located on the top surface side (upper side) of the semiconductor device 100, and a configuration located near the second main face 103 in the third direction Z corresponds to a configuration located on the bottom surface side (lower side) of the semiconductor device 100.

The semiconductor device 100 includes a plurality of divided device regions 105 on the first main face 102. The number and arrangement of the plurality of device regions 105 are arbitrary. Each of the plurality of device regions 105 includes a functional device formed using regions inside and outside the chip 101. The functional device includes, for example, at least one of a semiconductor switching device, a semiconductor rectifying device and a passive device. The functional device may include a circuit network in which at least two of a semiconductor switching device, a semiconductor rectifying device and a passive device are combined.

The semiconductor switching device includes, for example, at least one of a metal insulator semiconductor field effect transistor (MISFET), a bipolar junction transistor (BJT), an insulated gate bipolar junction transistor (IGBT) and a JFET. The semiconductor rectifying device may include at least one of a PN junction diode, a pin junction diode, a Zener diode, a Schottky barrier diode and a fast recovery diode. The passive device may include at least one of a resistor, a capacitor, an inductor and a fuse.

At least one of the plurality of device regions 105 includes an FET structure 106 (transistor structure). A voltage Vdg between drain and gate that applied to the FET structure 106 is, for example, 500 V or more and 1500 V or less. As described below, in the present embodiment, the FET structure 106 has a JFET structure. The structure of the FET structure 106 will be described below.

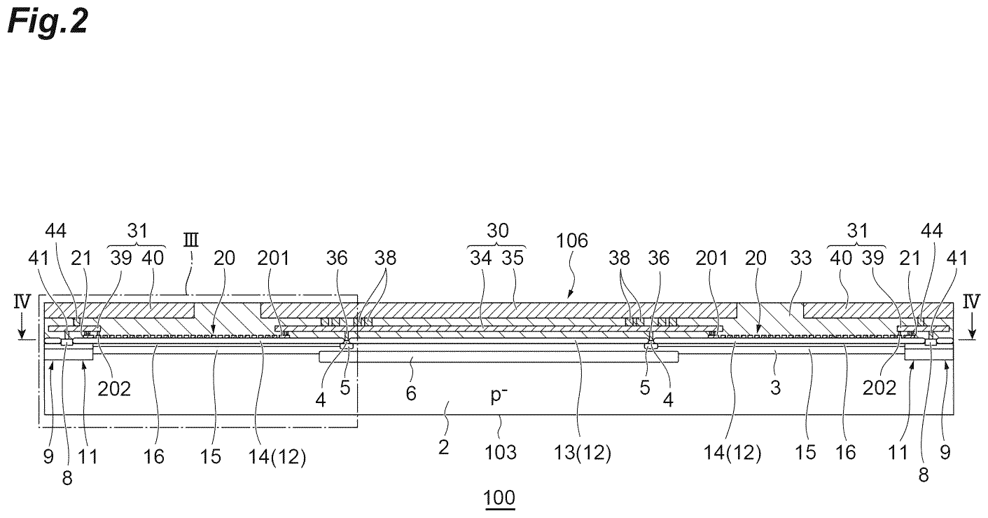

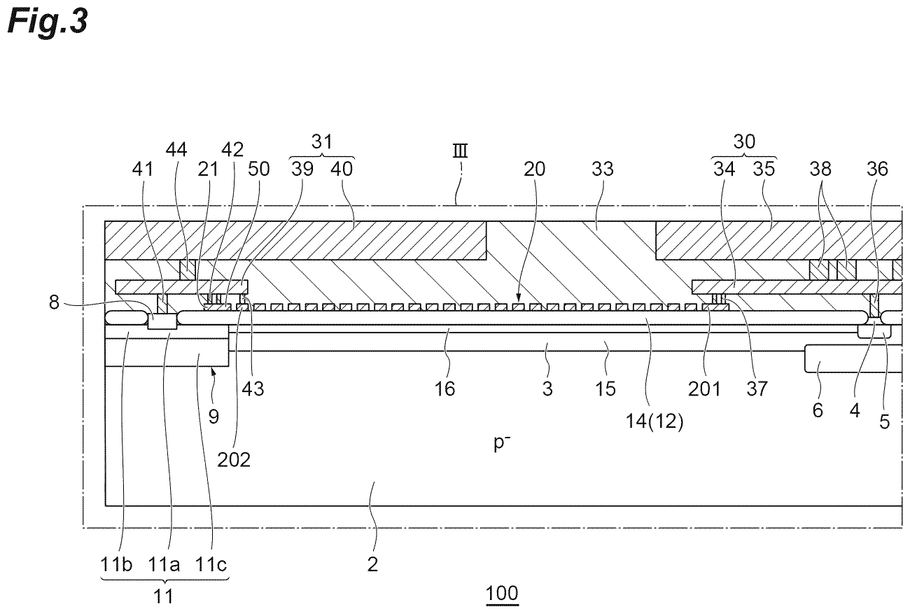

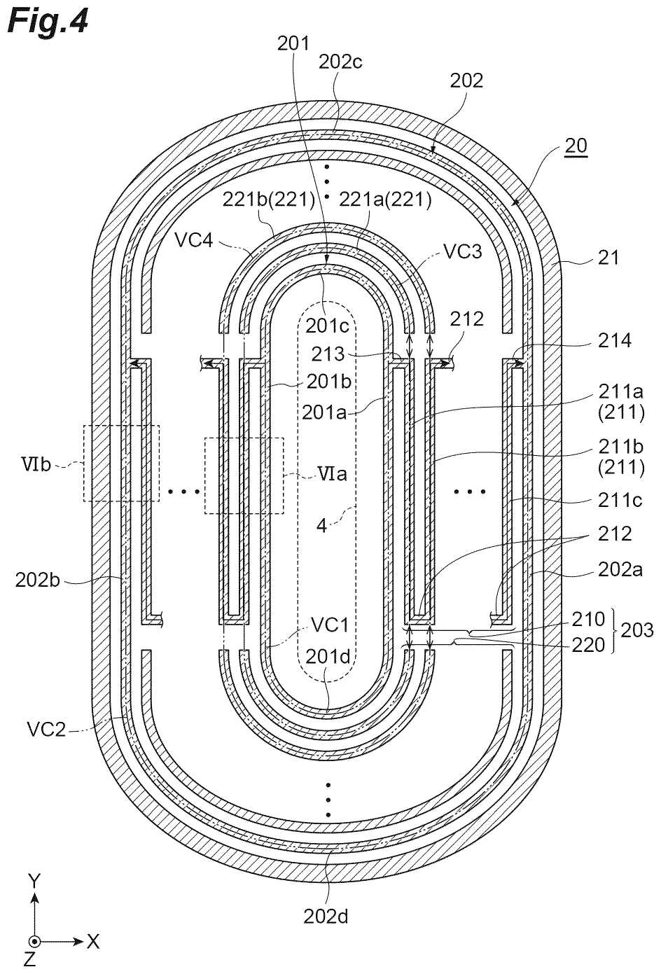

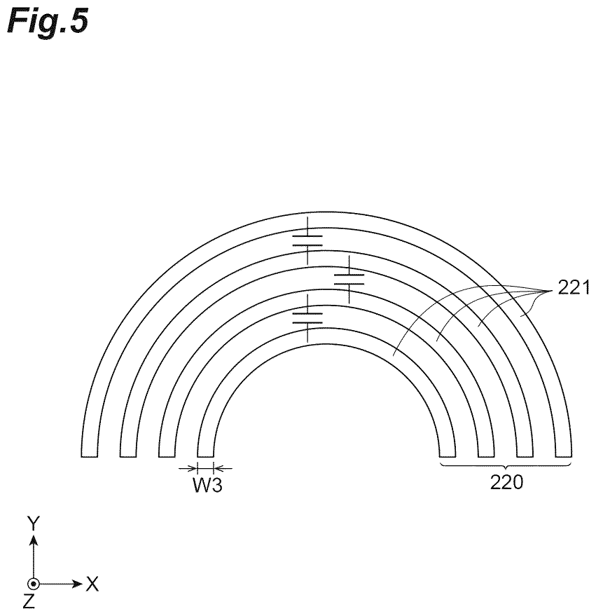

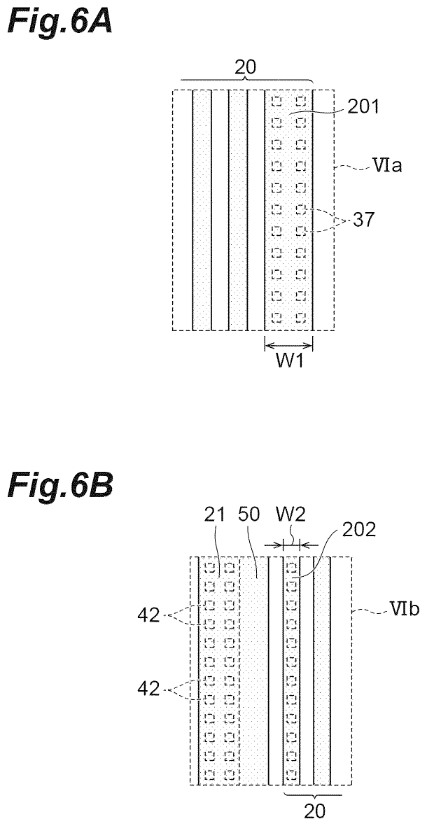

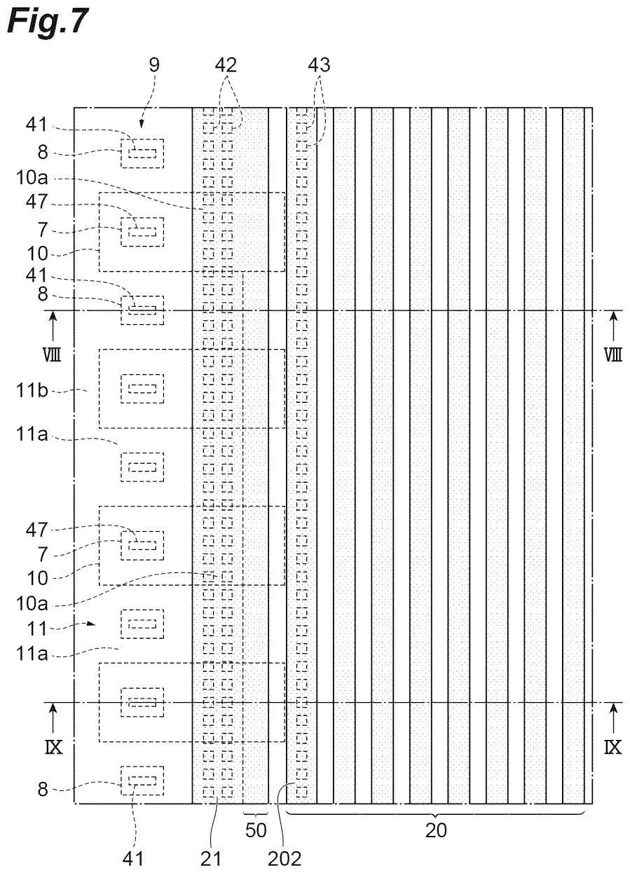

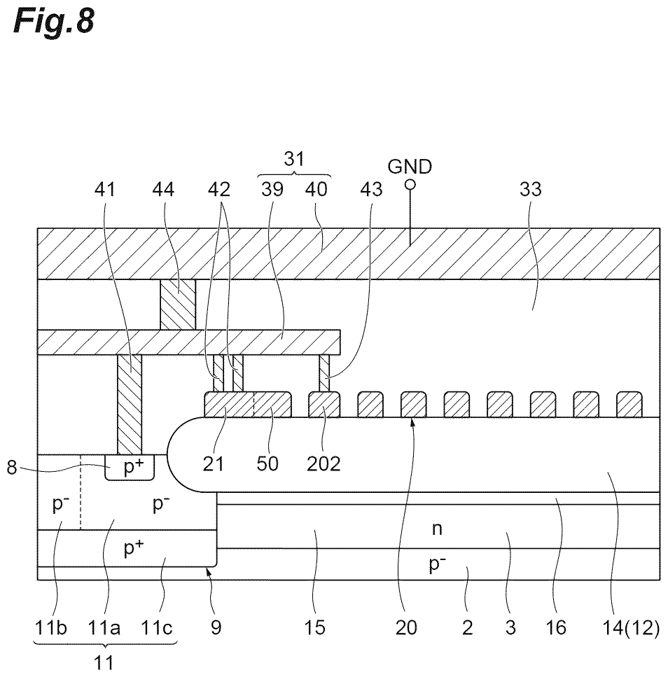

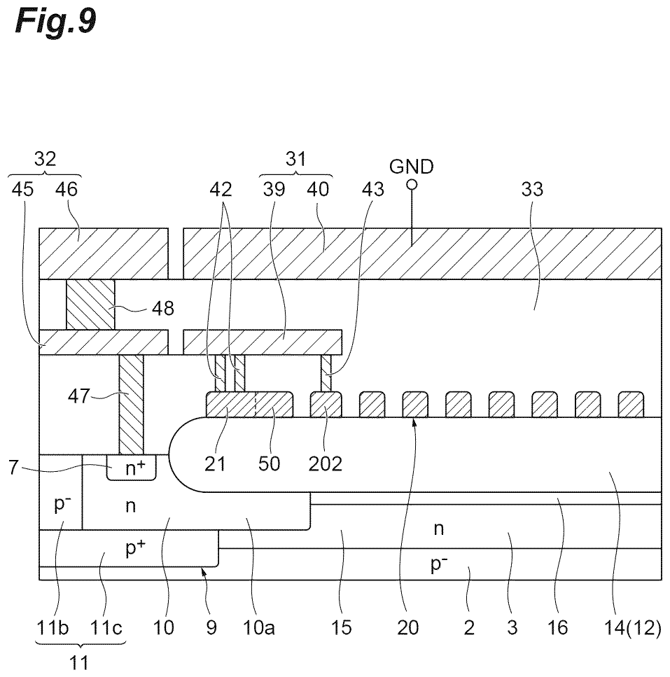

FIG. 2 is a schematic cross-sectional view taken along line II-II shown in FIG. 1. FIG. 3 is an enlarged view of a portion surrounded by an alternate long and short dash line III shown in FIG. 2. FIG. 4 is a cross-sectional view taken along line IV-IV shown in FIG. 2. FIG. 5 is an enlarged view of a main part of FIG. 4. FIG. 6A is an enlarged view of a portion surrounded by a broken line VIa in FIG. 4, and FIG. 6B is an enlarged view of a portion surrounded by a broken line VIb in FIG. 4. FIG. 7 is an enlarged view of a main part of FIG. 4. FIG. 8 is a schematic cross-sectional view taken along line VIII-VIII shown in FIG. 7. FIG. 9 is a schematic cross-sectional view taken along line IX-IX shown in FIG. 7.

As shown in FIG. 2 and the like, the FET structure 106 includes a semiconductor substrate 2 having a first conductivity type and a semiconductor layer 3 located on the semiconductor substrate 2 and having a second conductivity type. In the present embodiment, the first conductivity type is p-type, and the second conductivity type is n-type.

The semiconductor substrate 2 is a high-resistance silicon substrate. The p-type impurity concentration of the semiconductor substrate 2 is set to a relatively low value. In the present embodiment, the p-type impurity concentration of the semiconductor substrate 2 is, for example, 1.0×10¹³ cm⁻³ or more and 1.0×10¹⁴ cm⁻³ or less.

The semiconductor layer 3 is an epitaxial layer formed on the semiconductor substrate 2. The n-type impurity concentration of the semiconductor layer 3 is, for example, 1.0×10¹⁵ cm⁻³ or more and 1.0×10¹⁶ cm⁻³ or less. The thickness of the semiconductor layer 3 is, for example, 1 μm or more and 10 μm or less. A drain region 4 having the second conductivity type is located in the semiconductor layer 3.

The drain region 4 is a region that functions as a drain of the FET structure 106 and has an oval ring shape in a plan view. The n-type impurity concentration of the drain region 4 is higher than the n-type impurity concentration of the semiconductor layer 3. The n-type impurity concentration of the drain region 4 is, for example, 1.0×10¹⁹ cm⁻³ or more and 1.0×10²⁰ cm⁻³ or less. An n-type drain-side well region 5 in contact with the drain region 4 is formed below the drain region 4 in the semiconductor layer 3.

The drain-side well region 5 is a region covering a bottom portion and a side portion of the drain region 4, and has an oval ring shape surrounding the drain region 4 in a plan view. The n-type impurity concentration of the drain-side well region 5 is higher than the n-type impurity concentration of the semiconductor layer 3 and lower than the n-type impurity concentration of the drain region 4. The n-type impurity concentration of the drain-side well region 5 is, for example, 1.0×10¹⁶ cm⁻³ or more and 1.0×10¹⁷ cm⁻³ or less. An n-type drain buffer region 6 is formed below the drain-side well region 5.

The drain buffer region 6 is a region that forms a PN junction with the semiconductor substrate 2, and is located in the semiconductor substrate 2 and in the semiconductor layer 3 to cross the boundary between the semiconductor substrate 2 and the semiconductor layer 3. Since the drain buffer region 6 and the semiconductor substrate 2 form a PN junction portion, the breakdown voltage of the semiconductor device 100 is increased. The drain buffer region 6 has an oval shape in a plan view. The peripheral edge of the drain buffer region 6 is located outside the outer peripheral edge of the drain region 4 in a plan view. The n-type impurity concentration of the drain buffer region 6 is higher than the n-type impurity concentration of the drain-side well region 5 and lower than the n-type impurity concentration of the drain region 4. The n-type impurity concentration of the drain buffer region 6 is, for example, 1.0×10¹⁸ cm⁻³ or more and 1.0×10¹⁹ cm⁻³ or less.

As shown in FIGS. 7 to 9, a source/gate region 9 including an n-type source region 7 and a p-type gate region 8 is formed in the semiconductor layer 3. The n-type source region 7 and the p-type gate region 8 are electrically connected to each other and are alternately arranged at intervals. Therefore, a plurality of source regions 7 and a plurality of gate regions 8 are provided in the semiconductor layer 3. In the present embodiment, the source/gate region 9 is spaced apart from the drain region 4 and has an oval ring shape located around the drain region 4 in a plan view.

The source region 7 is in an electrically floating state and has a quadrangular shape in a plan view. The n-type impurity concentration of the source region 7 is substantially identical to the n-type impurity concentration of the drain region 4. The gate region 8 is electrically connected to ground (GND) and has a quadrangular shape in a plan view. The p-type impurity concentration of the gate region 8 is higher than the p-type impurity concentration of the semiconductor substrate 2. The p-type impurity concentration of the gate region 8 is, for example, 1.0×10¹⁹ cm⁻³ or more and 1.0×10²⁰ cm⁻³ or less.

The source/gate region 9 includes an n-type source-side well region 10 and a p-type gate-side well region 11. A plurality of source-side well regions 10 is provided in the semiconductor layer 3. The source-side well region 10 is located in the semiconductor layer 3 and below the source region 7. The gate-side well region 11 is located in the semiconductor substrate 2, in the semiconductor layer 3 and below the gate region 8.

The source-side well region 10 is a region that is in contact with the source region 7 and covers a bottom portion and a side portion of the source region 7. The plurality of source-side well regions 10 is intermittently formed. In a plan view, each source-side well region 10 surrounds the corresponding source region 7. The source-side well region 10 has a quadrangular shape in a plan view, and has a projected portion 10a projecting toward the drain region 4 more than the gate-side well region 11. A bottom portion of the source-side well region 10 is located in the semiconductor layer 3. The n-type impurity concentration of the source-side well region 10 is substantially identical to the n-type impurity concentration of the drain-side well region 5. Therefore, the n-type impurity concentration of the source-side well region 10 is lower than the n-type impurity concentration of the source region 7.

The gate-side well region 11 is a region that contacts the gate region 8 and covers a bottom portion and a side portion of the gate region 8. The gate-side well region 11 is formed in the semiconductor layer 3 so as to be in contact with a side portion and a bottom portion of the source-side well region 10 other than the projected portion 10a. A contact portion between the gate-side well region 11 and the source-side well region 10 forms a PN junction portion. The gate-side well region 11 includes a first region 11a located between two adjacent source-side well regions 10 each other, a second region 11b connecting the adjacent first region 11a, and a third region 11c located below the first region 11a and the second region 11b.

In the present embodiment, the p-type impurity concentration of the first region 11a is identical to the p-type impurity concentration of the second region 11b. The p-type impurity concentration of the third region 11c is higher than the p-type impurity concentration of the first region 11a and the p-type impurity concentration of the second region 11b. The p-type impurity concentration of the first region 11a and the second region 11b is, for example, 1.0×10¹⁷ cm⁻³ or more and 1.0×10¹⁸ cm⁻³ or less. The p-type impurity concentration of the third region 11c is, for example, 1.0×10¹⁸ cm⁻³ or more and 1.0×10¹⁹ cm⁻³ or less.

The first region 11a is a region that covers the bottom portion and the side portion of the gate region 8. The bottom portion of the first region 11a is located in the semiconductor layer 3 and has a quadrangular shape in a plan view. The second region 11b is a region located on the opposite side of the drain region 4 across the first region 11a. A bottom portion of the second region 11b is located in the semiconductor layer 3 and has an oval ring shape in a plan view. The third region 11c is a region formed in the semiconductor substrate 2 and in the semiconductor layer 3 so as to cross the boundary between the semiconductor substrate 2 and the semiconductor layer 3, and has an oval ring shape in a plan view. The third region 11c is in contact with the bottom portion of the first region 11a, the bottom portion of the second region 11b and a part of the bottom portion of each source-side well region 10. A bottom portion of the third region 11c is located in the semiconductor substrate 2, but is not limited thereto.

The current flowing between the drain region 4 and the source region 7 via the semiconductor layer 3 is controlled by applying a predetermined control voltage to the source/gate region 9. More specifically, when a predetermined control voltage is applied to the source region 7, a depletion layer expands from the PN junction portion formed by the source-side well region 10 and the gate-side well region 11. Thus, the source region 7 and the source-side well region 10 are depleted. As a result, a current path between the drain region 4 and the source region 7 is closed, so that no current flows between the drain region 4 and the source region 7. On the other hand, when the application of the control voltage to the source region 7 is released, the depletion of the source region 7 and the source-side well region 10 is released. As a result, the current path between the drain region 4 and the source region 7 is opened, so that current flows between the drain region 4 and the source region 7. In the FET structure 106, the current flowing between the drain region 4 and the source region 7 is controlled in this manner.

As shown in FIGS. 2, 3, 8 and 9, a local oxidation of silicon (LOCOS) film 12 as an example of an insulating layer that selectively exposes the drain region 4 and the source/gate region 9 is located above the semiconductor layer 3. The LOCOS film 12 is located between the drain region 4 and the source/gate region 9 in a plan view. The thickness of the LOCOS film 12 is, for example, 5000 Å or more and 15000 Å or less.

The LOCOS film 12 includes an inner LOCOS film 13 which has an oval shape in a plan view and covers a region surrounded by the drain region 4, and an outer LOCOS film 14 which has an oval ring shape in a plan view and covers a region between the drain region 4 and the source/gate region 9. The outer LOCOS film 14 covers one end portion of the projected portion 10a of the source-side well region 10 and one end portion of the gate-side well region 11. In the present embodiment, each one end portion corresponds to an end portion located above the semiconductor layer 3 and closest to the drain region 4.

In the semiconductor layer 3, a region overlapping the outer LOCOS film 14 corresponds to a drift region 15. The length of the drift region 15 is, for example, 80 μm or more and 200 μm or less. The length of the drift region 15 corresponds to the channel length of the FET structure 106. A p-type resurf layer 16 is formed in a part of the semiconductor layer 3 which in contact with the outer LOCOS film 14. The resurf layer 16 forms a PN junction portion with the drift region 15 in the semiconductor layer 3. In a plan view, the resurf layer 16 has an elliptical ring shape along the planar shape of the outer LOCOS film 14. The p-type impurity concentration of the resurf layer 16 is higher than the p-type impurity concentration of the semiconductor substrate 2. The p-type impurity concentration of the resurf layer 16 is, for example, 1.0×10¹⁵ cm⁻³ or more and 1.0×10¹⁶ cm⁻³ or less.

A resistive field plate 20 forming a current path CP is located on the outer LOCOS film 14. The field plate 20 has a function of suppressing disturbance of an electric field in the semiconductor layer 3 or the like, a function of suppressing local electric field concentration, a function of monitoring the voltage Vdg between drain and gate that is a high-voltage, and the like. The field plate 20 is disposed between the drain region 4 and the source/gate region 9 in a plan view. The field plate 20 functions as a resistor having a predetermined resistance value between the drain region 4 and ground. Thus, the field plate 20 forms the current path CP between the drain region 4 and ground. The resistance value of the field plate 20 is, for example, 20 MΩ or more and 100 MΩ or less. The field plate 20 comprises, for example, polysilicon which is rendered conductivity by doping. The impurity added to the polysilicon is phosphorus, boron, or the like. The resistance value of the field plate 20 can be adjusted by adjusting the quantity of the impurity (impurity concentration) added to the polysilicon. The impurity concentration in a part of the field plate 20 may be higher than the impurity concentration in other portions of the field plate 20. The field plate 20 has an innermost periphery 201, an outermost periphery 202 and an intermediate portion 203.

The innermost periphery 201 is a portion electrically connected to the drain region 4, and is closest to the drain region 4 in the field plate 20. Therefore, in a plan view, no field plate 20 is present inside the innermost periphery 201 of the field plate 20. The innermost periphery 201 constitutes a part of the current path CP formed by the field plate 20. As shown in FIGS. 6A and 6B, the width W1 of the innermost periphery 201 is larger than the width W2 of the outermost periphery 202, but is not limited thereto. The innermost periphery 201 has an oval shape in a plan view. The innermost periphery 201 includes: straight portions 201a, 201b which are separated from each other and extend along the second direction Y; a curved line portion 201c which is connected to one end of the straight line portion 201a, 201b and has a circular arc shape; and a curved line portion 201d which is connected to the other end of the straight line portion 201a, 201b and has a circular arc shape. Although not illustrated, each of the straight line portions 201a, 201b is located between the drain region 4 and the source/gate region 9 in the first direction X. Each of a part of the curved line portion 201c and a part of the curved line portion 201d is located outside the drain region 4 in the second direction Y. Therefore, the entirety of the straight line portions 201a, 201b, the other part of the curved line portion 201c and the other part of the curved line portion 201d overlap the region in which current flows in the FET structure 106 (operation region).

The outermost periphery 202 is a portion that is electrically connected to the source/gate region 9 and ground, and is closest to the source/gate region 9 in the field plate 20. Therefore, no field plate 20 is present outside the outermost periphery 202 of the field plate 20. As shown in FIGS. 4 and 7, in a plan view, the outermost periphery 202 is located closer to the drain region 4 than the projected portion 10a. The outermost periphery 202, as same as the innermost periphery 201, constitutes a part of the current path CP formed by the field plate 20. The outermost periphery 202 has an oval shape in a plan view. The outermost periphery 202 includes: straight portions 202a, 202b that are separated from each other and extend along the second direction Y; a curved line portion 202c that is connected to one ends of the straight portions 202a, 202b; and a curved line portion 202d that is connected to the other ends of the straight portions 202a, 202b. Although not shown, each of the straight line portions 202a, 202b is located between the drain region 4 and the source/gate region 9. Each of at least a part of the curved line portion 202c and at least a part of the curved line portion 202d is located outside of the drain region 4 in the second direction Y and has an arc shape.

The innermost periphery 201 is located on the virtual ellipse VC1, and the outermost periphery 202 is located on the virtual ellipse VC2. The virtual ellipses VC1 and VC2 are respectively parts of concentric ellipses centered on the drain region 4. Therefore, the innermost periphery 201 and the outermost periphery 202 are arranged on a virtual concentric ellipse having the drain region 4 as a center.

The intermediate portion 203 is a main portion in the field plate 20 and is located between the innermost periphery 201 and the outermost periphery 202. The intermediate portion 203 includes a path portion 210 that forms the current path CP and a non-path portion 220 that is spaced apart from the path portion 210 and located outside of the path portion 210 in the second direction Y. The path portion 210 includes a first portion located between the straight line portions 201a, 202a in the first direction X and a second portion located between the straight line portions 201b, 202b in the first direction X. The first portion and the second portion have a substantially identical shape. The non-path portion 220 includes a third portion located between the curved line portions 201c, 202c in the second direction Y and a fourth portion located between the curved line portions 201d, 202d in the second direction Y. The third portion and the fourth portion have a substantially identical shape. Therefore, the structure of the path portion 210 corresponding to the first portion and the structure of the non-path portion 220 corresponding to the third portion will be mainly described below.

The path portion 210 includes a plurality of straight line portions 211 extending along the second direction Y and spaced apart from each other, a plurality of first connection portions 212 connecting two straight line portions 211 adjacent to each other in the first direction X, a second connection portion 213 located closest to the innermost periphery 201 in the path portion 210, and a third connection portion 214 located closest to the outermost periphery 202 in the path portion 210. Each of the plurality of straight line portions 211, the plurality of first connection portions 212, the second connection portion 213 and the third connection portion 214 has a band shape in a plan view and constitutes a part of the current path CP. The plurality of straight line portions 211 is intermittently arranged in the first direction X. The interval between two adjacent straight line portions 211 is substantially constant. The width of each straight line portion 211 is also substantially constant. In the following description, among the plurality of straight line portions 211, a portion located closest to the innermost periphery 201 is referred to as a first straight line portion 211a, a portion located adjacent to the first straight line portion 211a in the first direction X is referred to as a second straight line portion 211b, and a portion located closest to the straight line portion 202a in the outermost periphery 202 is referred to as an outermost straight line portion 211c. The first straight line portion 211a is located adjacent to the straight line portion 201a (third straight line portion) in the innermost periphery 201 in the first direction X.

In the present embodiment, the plurality of straight line portions 211, the plurality of first connection portions 212, the second connection portion 213 and the third connection portion 214 are alternately disposed so that the path portion 210 has a bellows shape (zigzag shape) in a plan view. To be specific, one end of the first straight line portion 211a in the second direction Y and one end of the second straight line portion 211b in the second direction Y are connected to each other via one of the plurality of first connection portions 212 extending in the first direction X. At this time, each of an angle formed by the first straight line portion 211a and one of the first connection portions 212 and an angle formed by the second straight line portion 211b and one of the first connection portions 212 is a right angle or substantially a right angle. The other end of the first straight line portion 211a in the second direction Y and the straight line portion 201a in the innermost periphery 201 are connected to each other via the second connection portion 213 extending in the first direction X. At this time, each of an angle formed by the first straight line portion 211a and the second connection portion 213 and an angle formed by the straight line portion 201a and the second connection portion 213 is a right angle or substantially a right angle. The other end of the second straight line portion 211b in the second direction Y and another straight line portion 211 adjacent to the second straight line portion 211b are connected to each other via another one of the plurality of first connection portions 212. At this time, each of an angle formed by the second straight line portion 211b and another one of the first connection portions 212 and an angle formed by another straight line portion 211 and another one of the first connection portions 212 is a right angle or substantially a right angle. Similarly, one end of the outermost straight line portion 211c in the second direction Y and the straight line portion 202a in the outermost periphery 202 are connected to each other via the third connection portion 214 extending in the first direction X. At this time, each of an angle formed by the outermost straight line portion 211c and the third connection portion 214 and an angle formed by the straight line portion 202a and the third connection portion 214 is a right angle or substantially a right angle. In one example, while curved lines may not be used, only straight lines may be constituted to the path portion 210 in a plan view.

As shown in FIGS. 4 and 5, the non-path portion 220 has a plurality of curved line portions 221 spaced apart from each other and disposed along the second direction Y. Each of the plurality of curved line portions 221 is spaced apart from the innermost periphery 201, the outermost periphery 202 and the path portion 210 (i.e., the plurality of straight line portions 211, the plurality of first connection portions 212, the second connection portion 213 and the third connection portion 214). Each of the plurality of curved line portions 221 has an arc shape and is provided on a concentric circle. The plurality of curved line portions 221 is intermittently arranged in the second direction Y. Two curved line portions 221 adjacent to each other in the second direction Y may be capacitive coupled to each other via an interlayer insulating film 33 described later. From the viewpoint of uniformizing the capacitance difference, the interval between two curved line portions 221 adjacent to each other in the second direction Y is substantially constant. From the viewpoint of accurately and uniformly maintaining the interval, a width W3 of each curved line portion 221 may be larger as it is farther from the path portion 210 in the second direction Y. Hereinafter, among the plurality of curved line portions 221, a portion positioned closest to the innermost periphery 201 is referred to as a first curved line portion 221a, and a portion positioned adjacent to the first curved line portion 221a in the second direction Y is referred to as a second curved line portion 221b. The first curved line portion 221a is adjacent to the curved line portion 201c in the innermost periphery 201 in the second direction Y. The first curved line portion 221a is capacitive coupled to the curved line portion 201c. Among a plurality of the curved line portions 221a, as closer to the first curved line portion 221, its potential is higher or lower.

As shown in FIG. 4, the first curved line portion 221a is located on the virtual ellipse VC3 (on the first virtual ellipse) together with the first straight line portion 211a. The second curved line portion 221b is located on the virtual ellipse VC4 (on the second virtual ellipse) together with the second straight line portion 211b. The virtual ellipses VC3 and VC4 are parts of concentric ellipses centered on the drain region 4, similarly to the virtual ellipses VC1 and VC2. For this reason, each of the plurality of straight line portions 211 in the path portion 210 and the plurality of curved line portions 221 in the non-path portion 220 is disposed on a virtual concentric ellipse centered on the drain region 4.

As described above, the first portion and the second portion in the path portion 210 have a substantially identical shape, and the third portion and the fourth portion in the non-path portion 220 have a substantially identical shape. Therefore, each straight line portion included in the second portion is also arranged on the virtual concentric ellipse described above, and each curved line portion included in the fourth portion is also arranged on the virtual concentric ellipse described above. For example, among a plurality of the straight line portions included in the second portion, two straight line portions located on the opposite sides of the first straight line portion 211a and the second straight line portion 211b across the innermost periphery 201 in the first direction X are located on the virtual ellipses VC1 and VC2, respectively. Similarly, among a plurality of the curved line portions included in the fourth portion, two curved line portions located on the opposite sides of the first curved line portions 221a and the second curved line portions 221b across the innermost periphery 201 in the second direction Y are located on the virtual ellipses VC1 and VC2, respectively.

An outermost peripheral ground conductor film 21 electrically connected to ground is disposed on the outer LOCOS film 14 between the source/gate region 9 and the field plate 20 in a plan view. The outermost peripheral ground conductor film 21 has an annular shape surrounding the field plate 20 in a plan view. The outermost peripheral ground conductor film 21 is electrically connected to the gate region 8 and is not physically connected to the field plate 20. That is, the outermost peripheral ground conductor film 21 is separated from the field plate 20.

As shown in FIG. 7, the outermost peripheral ground conductor film 21 crosses the projected portion 10a of the source-side well region 10 and overlaps with the projected portion 10a in a plan view. The outermost peripheral ground conductor film 21 includes polysilicon to which impurities are added. The impurity concentration of the outermost peripheral ground conductor film 21 is, for example, identical to the impurity concentration of the innermost periphery 201 and the impurity concentration of the outermost periphery 202, but is not limited thereto.

A second ground conductor film 50 electrically connected to ground is disposed on the outer LOCOS film 14 between the field plate 20 and the outermost peripheral ground conductor film 21 in a plan view. In addition to the gate region 8, the outermost periphery 202 and the outermost ground conductor film 21, the second ground conductor film 50 is set to have the same potential (ground potential). By providing the second ground conductor film 50, the breakdown voltage of the semiconductor device 100 can be improved.

The second ground conductor film 50 has an oval ring shape surrounding the field plate 20 in a plan view. The second ground conductor film 50 crosses the projected portion 10a in a plan view and overlaps with the projected portion 10a. In the present embodiment, the second ground conductor film 50 is formed integrally with the outermost peripheral ground conductor film 21 along the inner of the outermost peripheral ground conductor film 21.

In such a configuration, the boundary between the semiconductor layer 3 and the projected portion 10a of the source-side well region 10 is disposed in a region between the inner peripheral edge of the second ground conductor film 50 and the outermost periphery 202 of the field plate 20 in a plan view. Therefore, the outermost periphery 202 of the field plate 20 is disposed closer to the drain region 4 side than the boundary between the semiconductor layer 3 and the projected portion 10a of the source-side well region 10.

A drain metal 30 electrically connected to the drain region 4, a gate metal 31 electrically connected to the gate region 8 and a source metal 32 electrically connected to the source region 7 are disposed above the semiconductor layer 3. A plurality of interlayer insulating films 33 is laminated above the semiconductor layer 3, and at least a part of the drain metal 30, at least a part of the gate metal 31 and at least a part of the source metal 32 are selectively formed in the interlayer insulating film 33.

The drain metal 30 includes a first drain metal 34 disposed above the drain region 4 and a second drain metal 35 disposed above the first drain metal 34. The first drain metal 34 overlaps the drain region 4 and the innermost periphery 201 of the field plate 20. The first drain metal 34 is electrically connected to the drain region 4 via a first contact 36 and electrically connected to the innermost periphery 201 via a second contact 37. The second drain metal 35 is electrically connected to the first drain metal 34 via a third contact 38.

The gate metal 31 includes a first gate metal 39 disposed above the gate region 8 and a second gate metal 40 disposed above the first gate metal 39. The first gate metal 39 overlaps the gate region 8, the outermost peripheral ground conductor film 21 and the outermost periphery 202 of the field plate 20. The first gate metal 39 is electrically connected to the gate region 8 via a fourth contact 41, electrically connected to the outermost peripheral ground conductor film 21 via a fifth contact 42 and electrically connected to the outermost periphery 202 via a sixth contact 43. The second gate metal 40 is electrically connected to, for example, a ground electrode (not shown) for supplying a ground potential. The second gate metal 40 is electrically connected to the first gate metal 39 via a seventh contact 44. As a result, the gate region 8, the outermost periphery 202 of the field plate 20 and the outermost peripheral ground conductor film 21 are set to have the same potential (ground potential). In the present embodiment, the first gate metal 39 of the gate metal 31 functions as a connecting member that electrically connects the gate region 8, the outermost periphery 202 and the outermost peripheral ground conductor film 21 each other. Therefore, the gate region 8, the outermost periphery 202 and the outermost peripheral ground conductor film 21 have the same potential (ground potential) via the gate metal 31.

The source metal 32 includes a first source metal 45 disposed above the source region 7 and a second source metal 46 disposed above the first source metal 45. The first source metal 45 overlaps the source region 7. The first source metal 45 is electrically connected to the source region 7 via an eighth contact 47. The second source metal 46 is electrically connected to the first source metal 45 via a ninth contact 48. The second source metal 46 set to be in an electrically floating state in a steady state. By applying a predetermined control voltage to the second source metal 46, the current flow between the drain region 4 and the source region 7 is controlled.

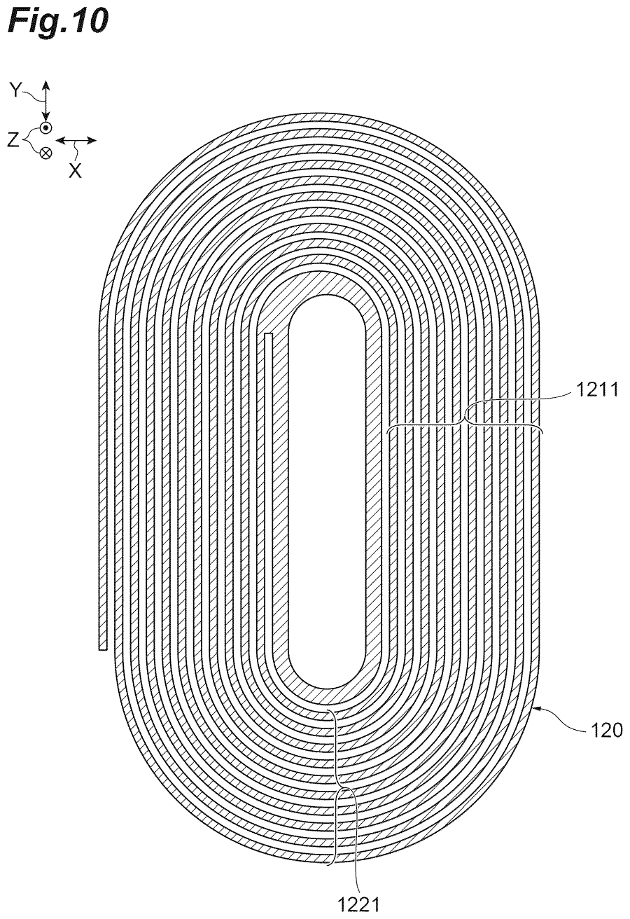

The operation and effect achieved by the semiconductor device 100 according to the present embodiment described above will be described with reference to a comparative example described below. FIG. 10 is a schematic plan view showing a field plate included in an FET structure according to the comparative example. As shown in FIG. 10, the field plate 120 included in the FET structure of the semiconductor device according to the comparative example has a shape of being spirally wound a plurality of times in a plan view. In the field plate 120, straight line portions 1211 and curved line portions 1221 are alternately and continuously provided along the electric path. Therefore, in the field plate 120, a current path is formed by both the straight line portions 1211 and the curved line portions 1221. Here, the path of current flowing through the curved line portions 1221 are likely to be non-uniform compared to the path of current flowing through the straight line portions 1211. Therefore, the actual electric resistance of the curved line portions 1221 are likely to vary more than the electric resistance of the straight line portions 1211. Since a large number of curved line portions 1221 are included in the field plate 120, variations in electric resistance of the curved line portions 1221 cannot be ignored depending on the use of the semiconductor device.

On the other hand, according to the present embodiment, in the field plate 20 included in the FET structure 106, the path portion 210 of the intermediate portion 203 located between the innermost periphery 201 and the outermost periphery 202 includes the plurality of straight line portions 211 extending in the second direction Y and the plurality of first connection portions 212 connecting two straight line portions 211 adjacent to each other in the first direction X. In addition, the first connection portion 212 extends in the first direction X. Therefore, the proportion occupied by the portion where the electric resistance is less likely to vary, in the electric path formed by the field plate 20, is larger than that in the comparative example. Therefore, according to the semiconductor device 100 of the present embodiment, it is possible to suppress the resistance variations of the field plate 20.

In one example, each of the innermost periphery 201, the outermost periphery 202 and the plurality of straight line portions 211 may be arranged in a virtual concentric oval shape centered on the drain region 4. In this case, for example, variations in the capacitive coupling between the innermost periphery 201 and the first straight line portion 211a, in the capacitive coupling between the outermost periphery 202 and the outermost straight line portion 211c and in the capacitive coupling within the plurality of straight line portions 211 are suppressed.

In one example, the field plate 20 includes the plurality of curved line portions 221 spaced apart from the innermost periphery 201, the outermost periphery 202 and the path portion 210 and adjacent to each other in the second direction Y. As a result, the breakdown voltage of the field plate 20 is favorably improved, so that the function of the field plate 20 is favorably exhibited.

In one example, the width W3 of the plurality of curved line portions 221 may be larger as they are farther from the straight line portion 211 in the second direction Y. In this case, the interval between two curved line portions 221 adjacent to each other in the plurality of curved line portions 221 can be favorably maintained. As a result, the capacitive coupling adjacent two curved line portions 221 is less likely to vary.

In one example, the first connection portion 212 may be connected to one end of the first straight line portion 211a in the second direction Y. In this case, a region the path portion 210 is provided can be efficiently utilized.

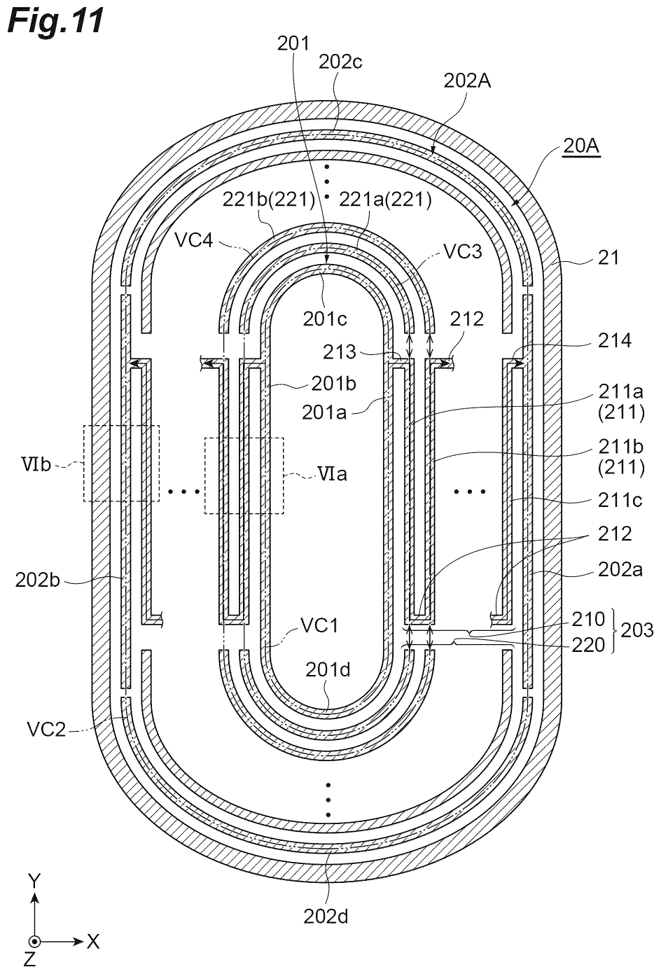

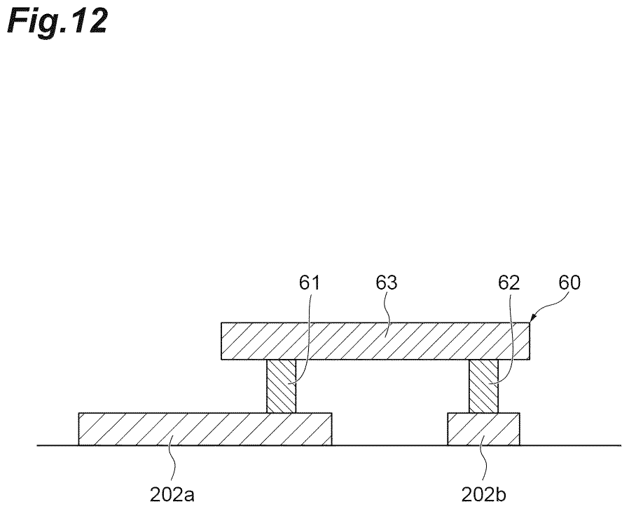

Hereinafter, a modification of the above-described embodiment will be described with reference to FIGS. 11 and 12. In the description of the modification, description redundant with the above-described embodiment will be omitted, and different portions will be described. That is, the description of the above-described embodiment may be appropriately used to the modification within a technically possible range.

FIG. 11 is a schematic plan view showing a field plate according to the modification. FIG. 12 is a schematic cross-sectional view for explaining the electrical connection between the straight line portion and the curved line portion in the outermost periphery. As illustrated in FIG. 11, in an outermost periphery 202A included in a field plate 20A, the straight line portions 202a, 202b and the curved line portions 202c, 202d are physically separated from each other. Here, as shown in FIG. 12, the straight line portion 202a and the curved line portion 202c are electrically connected to each other via a conductive member 60 located on the field plate 20A. The conductive member 60 has a contact 61 positioned on the straight line portion 202a and contacting with the straight line portion 202a, a contact 62 positioned on the curved line portion 202c and contacting with the curved line portion 202c and a bridge metal 63 contacting with the contacts 61, 62. The contacts 61, 62 are conductive portions that is formed simultaneously with the first contact 36, the second contact 37, and the like. The bridge metal 63 is a conductive portion formed simultaneously with the first gate metal 39 and the like. Although not illustrated, in the outermost periphery 202A, the straight line portion 202a and the curved line portion 202d, the straight line portion 202b and the curved line portion 202c, and the straight line portion 202b and the curved line portion 202d are electrically connected to each other via wiring similar to that of the conductive member 60. As a result, the overall potential of the outermost periphery 202A is favorably stabilized.

Also in the above-described modification, the same operation and effect as those of the above-described embodiment are exhibited. In the above-described embodiment and modification, the innermost periphery 201 may have a configuration similar to that of the outermost periphery 202A. As a specific example, in the innermost periphery 201, the straight line portions 201a, 201b and the curved line portions 201c, 201d may be physically separated from each other and electrically connected to each other via wiring or the like.

Although the embodiments and modifications of the present disclosure have been described above, the present disclosure can be implemented in still other forms.

In the above-described embodiment and modification, an example in which the LOCOS film is formed above the semiconductor layer has been described. However, STI (Shallow Trench Isolation) may be formed below the LOCOS film. The STI includes a trench formed by digging down a semiconductor layer and an insulator (silicon oxide, silicon nitride, or the like) buried in the trench.

In the above-described embodiment and modification, a configuration of which the conductivity types of various semiconductor regions are inverted may be adopted. That is, a p-type portion may be an n-type one, and an n-type portion may be a p-type one.

In the above-described embodiment and modification, the semiconductor device 100 can be applied to a power module used in an inverter circuit that drives an electric motor used as a power source of, for example, automobiles (including electric vehicles), trains, industrial robots, air conditioners, air compressors, fans, vacuum cleaners, dryers, refrigerators, and the like. In addition, the semiconductor device 100 can be also applied to a power module used in an inverter circuit of a solar battery, a wind power generator, another power generation device, or the like. Alternatively, the semiconductor device 100 can be applied to a circuit module constituting an analog control power supply, a digital control power supply, or the like.

Although the embodiments and modification according to one aspect of the present disclosure have been described in detail, these are merely specific examples used to clarify the technical content of the present disclosure, and the present disclosure should not be construed as being limited to these specific examples, and the scope of the present disclosure is limited only by the appended claims.

Hereinafter, characteristic examples extracted from the description of the specification and the drawings will be described.
[A1]
   A semiconductor device comprising:
a semiconductor substrate having a first conductivity type;
a semiconductor layer located above the semiconductor substrate, the semiconductor layer having a second conductivity type;
a drain region located in the semiconductor layer, the drain region having the second conductivity type;
a source/gate region including a source region having the second conductivity type and a gate region electrically connected to the source region, the gate region having the first conductivity type, the source/gate region being spaced from the drain region and located around the drain region;
an insulating layer located above the semiconductor layer and between the drain region and the source/gate region; and
a field plate located above the insulating layer, the field plate forming a current path,
wherein the field plate includes an innermost periphery electrically connected to the drain region, an outermost periphery electrically connected to a ground, a first straight line portion and a second straight line portion located between the innermost periphery and the outermost periphery and adjacent to each other in a first direction in a plan view, and a first connection portion connecting the first straight line portion and the second straight line portion,
wherein each of the innermost periphery, the outermost periphery, the first straight line portion, the second straight line portion and the first connection portion is a part of the current path,
wherein each of the first straight line portion and the second straight line portion extends in a second direction intersecting with the first direction in a plan view, and
   wherein the first connection portion extends in the first direction.
[A2] The semiconductor device according to [A1], each of the innermost periphery, the outermost periphery, the first straight line portion and the second straight line portion is disposed on a virtual concentric ellipse centered on the drain region.
[A3] The semiconductor device according to [A2], wherein the field plate further includes a first curved line portion and a second curved line portion adjacent to each other in the second direction, the first curved line portion and the second curved line portion being spaced apart from the innermost periphery, the outermost periphery, the first straight line portion and the second straight line portion,
wherein the first straight line portion and the first curved line portion are located on a first virtual ellipse included in the virtual concentric ellipse, and
   wherein the second straight line portion and the second curved line portion are located on a second virtual ellipse included in the virtual concentric ellipse.
[A4] The semiconductor device according to [A3], wherein each of a width of the first curved line portion and a width of the second curved line portion is larger as the first curved line portion and the second curved line portion are farther from the first straight line portion and the second straight line portion in the second direction.
[A5] The semiconductor device according to [A3] or [A4], wherein the field plate further includes a third curved line portion and a fourth curved line portion adjacent to each other in the second direction, the third curved line portion and the fourth curved line portion being spaced apart from the innermost periphery, the outermost periphery, the first straight line portion, the second straight line portion and the first connection portion,
wherein the third curved line portion and the fourth curved line portion are located opposite to the first curved line portion and the second curved line portion across the innermost periphery in the second direction,
wherein the third curved line portion is located on the first virtual ellipse, and
wherein the fourth curved line portion is located on the second virtual ellipse.
[A6] The semiconductor device according to any one of [A1] to [A5], wherein the first connection portion is connected to one end of the first straight line portion in the second direction.
[A7] The semiconductor device according to [A6], wherein the innermost periphery includes a third straight line portion adjacent to the first straight line portion in the first direction,
wherein the field plate further includes a second connection portion connecting the first straight line portion and the third straight line portion, and
   wherein the second connection portion is connected to the other end of the first straight line portion in the second direction.
[A8] The semiconductor device according to any one of [A1] to [A7], wherein at least one of the innermost periphery and the outermost periphery has an oval shape in a plan view.
[A9] The semiconductor device according to any one of [A1] to [A8], wherein at least one of the innermost periphery and the outermost periphery has a straight line portion and a curved line portion spaced apart from each other, and
wherein the straight line portion and the curved line portion are electrically connected via a conductive member located above the field plate.
[A10] The semiconductor device according to any one of [A1] to [A9], wherein the field plate includes polysilicon.
[A11] The semiconductor device according to any one of [A1] to [A10], wherein the semiconductor layer further includes:
a gate well region in contact with the gate region, the gate well region having the first conductivity type; and
a source well region in contact with the source region, the source well region having the second conductivity type, and
   wherein the source well region includes a projected portion projecting toward the drain region more than the gate well region.
[A12] The semiconductor device according to [A11], wherein, in a plan view, the outermost periphery is located closer to the drain region than the projected portion.

### REFERENCE SIGNS LIST

100; semiconductor device
2; semiconductor substrate
3; semiconductor layer
4; drain region
7; source region
8; gate region
9; source/gate region
10a; projected portion
20,20A; field plate
60; conductive member
201; innermost periphery
201a; straight line portion (third straight line portion)
201b,202a,202b,211; straight line portion
201c,201d,202c,202d,221; curved line portion
202,202A; outermost periphery
211a; first straight line portion
211b; second straight line portion
212; first connection portion
213; second connection portion
221a; first curved line portion
221b; second curved line portion
CP; current path
W1,W2,W3; width.

1. A semiconductor device comprising:
a semiconductor substrate having a first conductivity type;
a semiconductor layer located above the semiconductor substrate, the semiconductor layer having a second conductivity type;
a drain region located in the semiconductor layer, the drain region having the second conductivity type;
a source/gate region including a source region having the second conductivity type and a gate region electrically connected to the source region, the gate region having the first conductivity type, the source/gate region being spaced from the drain region and located around the drain region;
an insulating layer located above the semiconductor layer and between the drain region and the source/gate region; and
a field plate located above the insulating layer, the field plate forming a current path,
wherein the field plate includes an innermost periphery electrically connected to the drain region, an outermost periphery electrically connected to a ground, a first straight line portion and a second straight line portion located between the innermost periphery and the outermost periphery and adjacent to each other in a first direction in a plan view, and a first connection portion connecting the first straight line portion and the second straight line portion,
wherein each of the innermost periphery, the outermost periphery, the first straight line portion, the second straight line portion and the first connection portion is a part of the current path,
wherein each of the first straight line portion and the second straight line portion extends in a second direction intersecting with the first direction in a plan view, and
wherein the first connection portion extends in the first direction.

2. The semiconductor device according to claim 1, each of the innermost periphery, the outermost periphery, the first straight line portion and the second straight line portion is disposed on a virtual concentric ellipse centered on the drain region.

3. The semiconductor device according to claim 2, wherein the field plate further includes a first curved line portion and a second curved line portion adjacent to each other in the second direction, the first curved line portion and the second curved line portion being spaced apart from the innermost periphery, the outermost periphery, the first straight line portion and the second straight line portion,
wherein the first straight line portion and the first curved line portion are located on a first virtual ellipse included in the virtual concentric ellipse, and
wherein the second straight line portion and the second curved line portion are located on a second virtual ellipse included in the virtual concentric ellipse.

4. The semiconductor device according to claim 3, wherein each of a width of the first curved line portion and a width of the second curved line portion is larger as the first curved line portion and the second curved line portion are farther from the first straight line portion and the second straight line portion in the second direction.

5. The semiconductor device according to claim 3, wherein the field plate further includes a third curved line portion and a fourth curved line portion adjacent to each other in the second direction, the third curved line portion and the fourth curved line portion being spaced apart from the innermost periphery, the outermost periphery, the first straight line portion, the second straight line portion and the first connection portion,
wherein the third curved line portion and the fourth curved line portion are located opposite to the first curved line portion and the second curved line portion across the innermost periphery in the second direction,
wherein the third curved line portion is located on the first virtual ellipse, and
wherein the fourth curved line portion is located on the second virtual ellipse.

6. The semiconductor device according to claim 1, wherein the first connection portion is connected to one end of the first straight line portion in the second direction.

7. The semiconductor device according to claim 6, wherein the innermost periphery includes a third straight line portion adjacent to the first straight line portion in the first direction,
wherein the field plate further includes a second connection portion connecting the first straight line portion and the third straight line portion, and
wherein the second connection portion is connected to the other end of the first straight line portion in the second direction.

8. The semiconductor device according to claim 1, wherein at least one of the innermost periphery and the outermost periphery has an oval shape in a plan view.

9. The semiconductor device according to claim 1, wherein at least one of the innermost periphery and the outermost periphery has a straight line portion and a curved line portion spaced apart from each other, and
wherein the straight line portion and the curved line portion are electrically connected via a conductive member located above the field plate.

10. The semiconductor device according to claim 1, wherein the field plate includes polysilicon.

11. The semiconductor device according to claim 1, wherein the semiconductor layer further includes:
a gate well region in contact with the gate region, the gate well region having the first conductivity type; and
a source well region in contact with the source region, the source well region having the second conductivity type, and
wherein the source well region includes a projected portion projecting toward the drain region more than the gate well region.

12. The semiconductor device according to claim 11, wherein, in a plan view, the outermost periphery is located closer to the drain region than the projected portion.
